(19) United States
(12) Patent Application Publication
(10) Pub. No.: US 2015/0377979 A1
(43) Pub. Date: Dec. 31, 2015

(54) METHOD FOR TESTING AN ENERGY STORE IN A MOTOR VEHICLE

(71) Applicant: AUDI AG, Ingolstadt (DE)

(72) Inventors: KARSTEN BARTH, Chemnitz (DE); ROLF WAGNER, Ingolstadt (DE)

(73) Assignee: AUDI AG, Ingolstadt (DE)

(21) Appl. No.: 14/767,853

(22) PCT Filed: Jan. 24, 2014
(86) PCT No.: PCT/EP2014/000181

§ 371 Date: Aug. 13, 2015

(30) Foreign Application Priority Data
Feb. 14, 2013 (DE) 10 2013 002 589.3

(51) Int. Cl. G01R 31/36

(52) U.S. Cl. CPC G01R 31/3693; G01R 31/362; G01R 31/3682

(57) ABSTRACT

A motor vehicle has a first energy store for the operation of multiple vehicle systems and a second energy store which, at least, provides the electrical energy needed to start the motor vehicle, and a control device. A method for testing a first energy store includes connecting the first energy store to a load having a lower impedance than the minimum total impedance of a parallel circuit composed of a fixed selection of the vehicle systems for a fixed time interval by means of the control device, measuring a voltage dropping on the first energy store by means of the voltage measuring device, at least once within the time interval, and outputting a signal by means of the control device if the voltage falls below a predefined limiting value,

The invention relates to a method for testing of a first energy store in a motor vehicle, which includes a first energy store for operating several vehicle systems and a second energy store, which provides at least the electrical energy required to start the motor vehicle, and a control device.

Eco-friendliness and low fuel consumption are increasingly becoming important selection criteria for the selection of a motor vehicle. This causes an increasing development of motor vehicles with an electric drive or a hybrid drive. In particular motor vehicles, where the hybridization goes beyond a pure automatic start-stop system with energy recovery, have typically a higher voltage energy store operating the at least one electric motor or starter generator installed in the motor vehicle. However, a variety of loads in the onboard electrical system are advantageously operated at a lower operating voltage, for example 12V. Therefore, a low-voltage energy store is frequently provided. Even when using in a motor vehicle only a single operating voltage, employing two separate onboard electrical systems having a dedicated energy store is often advantageous. Thus, the motor vehicle includes two onboard electrical systems, of which one is frequently operated at high voltages and another at low-voltages. These onboard systems are frequently coupled via a DC/DC converter.

To ensure a reliable operation of all vehicle systems, it is essential that the performance and the state of charge of energy stores in the motor vehicle can be tested. In a conventional motor vehicle having an onboard electrical system, an energy store and a combustion engine, the performance of the energy store is already being tested upon starting, since very large currents are drawn in this situation. If the voltage drop across the energy store remains in this case high enough to allow starting of the motor vehicle, then it can be assumed that the state of the energy store is sufficient to ensure safe operation of all vehicle systems.

In particular, the or one of the already existing electric motors or a starter generator, in particular a belt driven starter generator or a crankshaft starter generator, are nowadays often used in hybrid vehicles as a starter for the internal combustion engine. The starter of the engine is hereby partially powered from a second energy store, which is integrated in the vehicle in addition to a first energy store that supplies other vehicle systems. Thus, the first energy store is not burdened. Although as a rule, the voltage drop across the first energy store is measured; conclusions from the voltage drop in the unloaded state can be applied to the state of charge and the performance of the first energy store only in a limited fashion.

As explained at the onset, the first energy store in many motor vehicles is a low-voltage energy store and the second energy store is a higher voltage energy store. In the examples and descriptions given in this application, the term low-voltage energy store is therefore used for sake of greater clarity for the first energy store and the term higher voltage energy store for the second energy store. However, this is not intended as limiting the generality of these descriptions and examples, because both energy stores can of course have the same rated voltage and, in some situations, the first energy store may even have a higher nominal voltage than the second energy store.

It is thus the object of the invention to provide a method for testing a first energy store that allows more reliable testing of the adequate performance and the adequate state of charge of the first energy store for operating the vehicle systems.

The object is solved by the invention by a method of the aforementioned type, which includes the following steps:

connecting with the control device the first energy store to a load with lower impedance than the minimum total impedance of a parallel circuit composed of a specified selection of vehicle systems, for a fixed time interval,
measuring with the voltage measuring device a voltage drop at the first energy store at least once within the time interval,
outputting with the control device a signal, when the voltage drop is less than a predetermined limiting value.

The method according to the invention is based on the idea that a reliable statement about the performance and the state of charge of an energy store is only possible under load. To ensure that the first energy store is equipped to handle all loads that occur when driving, the load under which the behavior of the first energy store is examined should be at least as large as the load during driving. It is particularly advantageous if the load for testing is greater than the load of all vehicle system, i.e. the impedance of the load connected to the first energy store for testing is lower than the impedance of a parallel connection of the vehicle systems to be used at the same time. Advantageously, the load should have a low inductance. In this case, large currents flow immediately when the load is connected to the first energy store and very short time intervals can be used for testing of the first energy store.

When the voltage drop at the first energy store is now measured during the time interval in which the first energy store is connected to the load, this voltage is a very good indication of the performance of the first energy store. When the time interval is sufficiently long, so that inductance and capacitance of the energy store as well as of the load connected to the energy store do not affect the measured voltage, this voltage is proportional to the quotient of the resistance of the load and the sum of the resistance of the load and of the internal resistance the first energy store. The measured value therefore depends only on the internal resistance of the energy store when the resistance of the load is fixed. However, the internal resistance of an energy store is the decisive criterion for the performance of an energy store.

When in the method according to the invention, the voltage across the first energy store in the measurement during the time interval drops below a predetermined limiting value, this indicates that a maximum internal resistance of the first energy store is exceeded. Since the electric power for starting the motor vehicle is taken from the second energy store, an operation of the motor vehicle is still possible in this case. According to the invention, however, a warning signal is outputted by an output device to alert the driver to the limited performance of the first energy store. The driver is thereby informed that when driving, not all vehicle system may be adequately powered.

It is also possible to change additional settings on the motor vehicle depending on the measured voltage and the driving state of the motor vehicle. For example, if the motor vehicle has not been put into operation and a very low-voltage was measured, a start of the vehicle can be completely prevented. It is also possible that various types of warning signals are outputted depending on the measured voltage. For example, when the measured voltage drops below a first limiting value, a warning light may be activated, which flashes when dropping below another, lower limiting value, and which is complemented by an acoustic signal when the measured voltage drops below a still lower third limiting value.

It is also possible that individual, non-safety-relevant vehicle systems may be disabled. In particular, for example entertainment systems in the motor vehicle may be shut down when the measured voltage drops below a first limiting value, and all non-safety-related vehicle systems powered by the first energy store may be switched off when the measured voltage drops below another limiting value. It is also possible that the first energy store is completely disconnected from the onboard electrical system when the measured voltage drops below a predetermined limiting voltage value in order to enable, for example, an exclusive operation of all low-voltage components via the DC/DC converter and the higher-voltage energy store or in order to prevent a deep discharge of the first energy store.

The motor vehicle may also have several control devices. In this case, the signal can also be outputted to other vehicle components by another control device different from the connection of the first energy store with the load. In addition, several loads may also be connected to the first energy store.

It is possible that the first energy store is a low-voltage energy store and the second energy store is a higher voltage energy store. Many components of a motor vehicle are designed to operate on a 12 V onboard electrical system. Since lower operating voltages both for semiconductor electronics and for illumination devices can be expected in the future, the voltage of the onboard electrical system may in the medium term be reduced further. At the same time, a higher operating voltage, for example 48V, is advantageous for operating electric motors and starter generators. Consequently, it is advantageous to use a low-voltage energy store as an energy store for supplying a low-voltage onboard electrical system and a higher energy store for operating a higher-voltage onboard electrical system.

Of course, it is also possible to use the method according to the invention in motor vehicles having more than two separate onboard electrical systems with associated energy stores. In this case, the method can be used for testing a plurality of energy stores, especially those that do not provide power to start and/or operate a motor used for driving.

Advantageously, the steps may be performed before each trip, especially when switching on the ignition of the motor vehicle, when opening a vehicle door and/or upon detection by a detection device of a remote control key belonging to the vehicle at a predetermined maximum distance, and/or at regular intervals, especially when operating the motor vehicle or when the motor vehicle is idle. Performing the steps of the method according to the invention, when switching on the ignition of the motor vehicle, corresponds essentially to the inherent testing of an energy store in a conventional motor vehicle when starting the motor vehicle. The same degree of operational reliability is thus produced with a conventional motor vehicle. To avoid a delay of the commencement of a trip due to the test procedure, the test procedure may advantageously already be performed before the ignition is switched on. The test procedure may also be performed at times when a prospective start of the vehicle appears likely, for example already when the driver-side door is opened or the motor vehicle is unlocked, or when the driver approaches, which can be determined, for example, by determining a distance or detecting a wireless control key, for example, by measuring the signal strength.

When first energy stores are used in situations where frequent heavy loading is not detrimental to the life time of the first energy store, it is still advantageous to carry out the steps of the method according to the invention at regular intervals. Such a test may be performed, for example, every 10 or every 50 kilometers or, for example, once every hour of driving time of the motor vehicle. Alternatively or additionally, such a test can also be performed for certain driving situations or use situations of the motor vehicle. For example, such a test may be performed before using an entertainment system, which requires large amounts of energy. Also, the first energy store may be tested when exceeding a certain speed, thereby ensuring that all vehicle systems operate in particular at high speed. A test may also be performed at fixed intervals when the motor vehicle is parked. At least one control device of a modern motor vehicle is often active even in a parked motor vehicle. This control device can then be used to perform the test method regularly, for example every 24 hours, even in a parked motor vehicle. This can be done in particular when a certain minimum time of inactivity is exceeded.

Advantageously, the load may be a bidirectional DC/DC converter of the motor vehicle. Many hybrid vehicles already have a bidirectional DC/DC converter, so that both the low-voltage electrical system can be supplied from the higher voltage system and the higher voltage electrical system can be supplied from the low-voltage system. Supplying energy to the low-voltage system from the higher voltage system is advantageous because a separate alternator for charging the low-voltage energy store and operating the vehicle systems powered by the low-voltage system can then be dispensed with. The low-voltage energy store of the motor vehicle is then charged exclusively by operating the electric motor or one of the electric motors as a generator. Provisions for powering the higher-voltage system from the low-voltage system in the motor vehicle are usually made primarily to enable a jump-start of the motor vehicle by another motor vehicle, which has only a low-voltage system.

It is essential for the method according to the invention that the DC/DC converter can be operated so that energy can be withdrawn from the first voltage electrical system, which includes the first energy store, and transported into the second voltage electrical system, which includes the second energy store. For this purpose, for example in the presence of a higher voltage electrical system and a low-voltage electrical system, the DC/DC converter can be operated so that the voltage on the higher voltage side of the DC/DC converter is higher than the voltage drop at the higher voltage energy store. The output voltage can be adjusted differently depending on the design of the DC/DC converter. In the simplest case, the conversion factor of the DC/DC converter can be adjusted directly, for example by pulse-width-modulation of the control signal. However, most DC/DC converters are operated in a controlled fashion, in which case control is performed via a control circuit. Such control produces a stable output voltage in the event that the load or the input voltage changes.

In the step of connecting the first energy store to the load, a reference voltage or a reference current of the DC/DC converter can initially be adapted, whereafter the DC/DC converter is operated for the length of the time interval with the adjusted reference voltage or the adjusted reference current. As a rule, the DC/DC converter is operated in a hybrid vehicle so that a low-voltage energy store is charged from the higher voltage electrical system. In order to briefly burden the low-voltage energy store with a load having a low impedance, the reference voltage or the reference current on a controlled DC/DC converter may be adjusted so that the output voltage of the DC/DC converter is briefly set substantially higher than the voltage drop across the higher voltage energy store. In this case, electrical energy is transported from the low-voltage electrical system to the higher-voltage electrical system, with the transported energy originating from the low-voltage energy store. The low-voltage energy store is thus discharged. The DC/DC converter itself has a very low resistance. Because the voltages are converted to a higher voltage than the voltage drop across the higher-voltage energy store, the higher voltage energy store is charged and therefore represents a load. The internal resistance of the higher-voltage energy store is generally low. This resistance seems even lower for the current flow of the low-voltage energy store, since the voltage is increased prior by the DC/DC converter. In the described mode of operation, the DC/DC converter as a whole thus serves a low-impedance load for the first energy store,

In order to achieve short time intervals, the DC/DC converter may advantageously be disconnected from the first and/or second energy store, or the operation of the DC/DC converter may be interrupted before the reference voltage or the reference current is adjusted. In this case, the operation of the DC/DC converter, if it is in operation, is initially interrupted, the reference voltage or reference current is then adjusted, whereafter the DC/DC converter resumes its operation.

Advantageously, the current supplied by the load is used in the time interval to charge the second energy store, or the load is a motor, a starter generator or a heating device. When the second energy store is charged, the method according to the invention can be performed virtually without any energy loss. The higher voltage energy source can be charged by the load in particular when the load is, as described above, a DC/DC converter. Alternatively, however, charging can also take place with a motor as a load and a downstream generator or the like. In particular, when the current is consumed by a motor, the current can be consumed even when the motor is stopped, for example, by the short-circuiting of the motor windings. The current can also be consumed to power a heater. Advantageously, this may be a heating device of the motor vehicle.

If the inductance of the load or of the first energy store is not too high, a very high current flow from the first energy store through the load is reached almost immediately after the first energy store is connected to the load. Further voltage measurements yield no further information once the voltage drop at the first energy store has stabilized after making the connection. The time interval should therefore be limited so that the output voltage of the first energy store can stabilize after the connection, whereafter at least one measurement should be performed, with additional measurements only serving to reduce the noise; afterwards, the load can again be disconnected from the first energy store. The time interval is hence advantageously between 2 ms and 60 s, in particular between 200 ms and 40 s, and more specifically between 1 s and 30 s. Should the stabilization time for the voltage drop at the first energy store after making the connection change substantially as a function of one or more parameters, the voltage drop may advantageously be measured continuously after making the connection, wherein a stabilized voltage is defined as an end condition of the time interval, for example a maximum difference between two successive voltages or a maximum interval for several successive voltages.

The impedance of the load may be selected so that the current supplied during the time interval at a functional first energy store that does not output a signal has a maximum magnitude of at least 40 A, preferably of at least 200 A, more specifically at least 300 A. When starting a conventional motor vehicle, currents of up to 700 A are supplied by the energy store of the motor vehicle. In conventional motor vehicles, the energy store, usually a lead-acid battery, is therefore tested with very high currents. If no starter motor is to be operated by the first energy store, it is often not necessary in normal operation to make such high currents available. Nevertheless, it may be advantageous to burden the first energy store with a maximum current magnitude that is far above the maximum current magnitude used when driving. An optimal smallest maximum current can be selected by selecting a suitable load or by suitably controlling a DC/DC converter.

When the control device outputs a signal, a warning signal can be outputted to the driver by a notification device of the motor vehicle, in particular as acoustic, visual or haptic notification. While non-existence of the testing method according to the invention initially does not prevent operation of the motor vehicle, it is nevertheless important to inform a driver of this non-existence of the test. Such notification may take place visually, for example via a warning light on the dashboard. However, warning lights on the dashboard are not correctly noticed by some drivers. Therefore, an audible warning, such as a hum, a regular beep or the like may alternatively or additionally be outputted or the driver can be alerted haptically, for example by vibrations of the steering wheel or the like, that a reliable operation of all vehicle systems cannot be ensured with the current state of the first energy store.

It is possible that a safe driving operation with a first energy store having insufficient performance cannot be ensured in some vehicles. Therefore, alternatively or additionally, the motor vehicle can be shut down by outputting with the control device a signal, in particular when the motor vehicle is standing still.

It is also possible that when the control device outputs a signal, the use of at least one vehicle system, especially a communication, entertainment, driving assistance, sensor, heating or air-conditioning system and/or navigation system may be inhibited. This is particularly advantageous, since even a first energy store, which lacks the performance for reliably operating all vehicle systems of the motor vehicle, may frequently still have sufficient power to operate the safety-relevant systems of the motor vehicle when additional functions are prevented from being used or when these systems are disconnected from the onboard electrical system.

In addition or alternatively, the first energy store may be disconnected from the onboard electrical system of the motor vehicle when the control device outputs a signal. This may be prevented, for example, by deep discharging the energy store.

It is also possible to inhibit, after the control device outputs a signal, a change in an operating mode of the motor vehicle with a purely electrical driving operation and/or to exit such mode. The second energy store is thereby initially dismissed in many vehicles. The energy obtained from generators in the motor vehicle can then, for example, be supplied to the first energy store or the first energy store can be charged and charged more quickly by the second energy store.

Furthermore, the invention relates to a motor vehicle which includes a first energy store for operating several vehicle systems and a second energy store, which supplies at least the electrical energy required to start the motor vehicle, a voltage measuring device, and at least one control device, wherein the motor vehicle is designed to perform an aforedescribed method. For this purpose, the vehicle must have a low impedance load, wherein the control device is designed to connect this load to the first energy store for performing the method.

In particular, the control device may be designed to determine a lower limit of the voltage drop at the first energy store, to read out the voltage measured by the voltage measurement device and to output an alarm signal when the measured voltage is lower than the lower limit. As described above, the maximum internal resistance of the first energy store defines the specified lower limiting value of the voltage where the alarm is not yet outputted. The control device may, if the voltage measuring device reads the voltage at the first energy store periodically, simply retrieve the last read value from a buffer. Alternatively, the control device may control the voltage measuring device such that it measures the voltage drop at the first energy store. Advantageously, the control device may be designed such that the voltage drop at the first energy store can be read out at any time, i.e. also outside the method for testing the first energy store. In this way, a decrease in the voltage at the first energy store and thus a diminished performance can in many situations be detected in absence of a load or with a load that is generated during normal operation of the onboard electrical system. For example, the same warning light that is activated when it is detected that the battery voltage drops below a first limiting voltage value with a low-impedance load, will also be activated when the voltage drops below a second limiting value in normal operation.

In addition, the control device or another control device may be configured to connect the first energy store to a load having a lower impedance than the minimum total impedance of a parallel circuit formed of a predetermined selection of the vehicle systems and to evaluate the alarm signal. The control device may, for example, control a switch that connects the load to the first energy store. However, the load may also be a device whose consumption is controlled by the control device. In this case, the consumption of the load may be increased to perform the test procedure.

When two separate control devices are used, the control device that connects the first energy store to the load and also disconnects the first energy store from the load may also be configured to receive the alarm signal from the control device monitoring of the first energy store and to output, depending on this signal, another signal or to directly control a display element or other elements for outputting information.

In a particularly advantageous embodiment, the load may be a DC/DC converter and the control device, the additional control device or a third control device may be designed to set the target current or target voltage of the DC/DC converter. As described above, by changing the target current or the target voltage of a DC/DC converter, a DC/DC converter, in particular a bidirectional DC/DC converter that is used in normal operation for charging the first energy store, can serve as a load having a low impedance. This is particularly advantageous since the second energy store can then be charged with the energy supplied by the first energy store, thereby minimizing energy losses.

When a DC/DC converter that charges a second energy store is used as a load for the first energy store, no separate component representing a load is required. Since a large part of the energy supplied by the low-voltage energy store can be stored in the second energy store, little power is dissipated. No additional heat is thus generated, making additional cooling of the load unnecessary.

The motor vehicle may for example be designed such that the first control device is a low-voltage energy management, which monitors the low-voltage electrical system of the motor vehicle and regularly and periodically measures the voltage drop at the first energy store. Such low-voltage energy management may be designed to send signals to other components when the voltage drops below one or more stored lower voltage limiting values. Another control device can serve as a higher voltage coordinator which can, for example, switch the DC/DC converter on and off and/or can connect the DC/DC converter to or disconnect the DC/DC converter from the energy stores. In addition, this higher voltage coordinator receives the signals of low-voltage energy management and can therefore issue a warning to the driver via a cockpit instrument when the voltage drops below the predetermined voltage limiting value.

A higher voltage coordinator that monitors and regulates the voltage in the higher-voltage electrical system of the motor vehicle can serve as the third control device. The higher voltage coordinator can be configured to adjust the target voltage and the target current of the DC/DC converter.

The method according to the invention can therefore be carried out in such vehicle by the higher voltage coordinator that controls the control devices associated with the higher voltage energy management and low-voltage energy management and can receive their signals.

It will be understood that the motor vehicle may include any number of control devices that can be used to perform the method according to the invention. The vehicle may also include any number of onboard electrical systems with an arbitrary number of associated energy stores, wherein the motor vehicle may include one or more control devices configured to carry out the method for testing several or all of these energy stores.

Further advantages and details of the invention will become apparent from the following exemplary embodiments and the drawings. These show in:

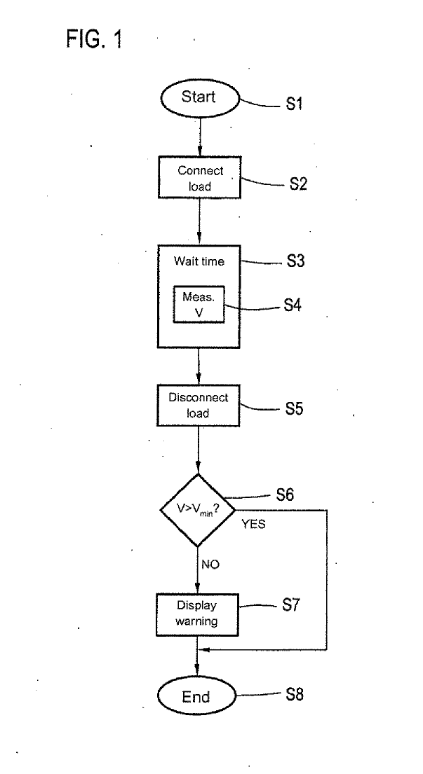

FIG. 1 a flow diagram of an exemplary embodiment of the method according to the invention,

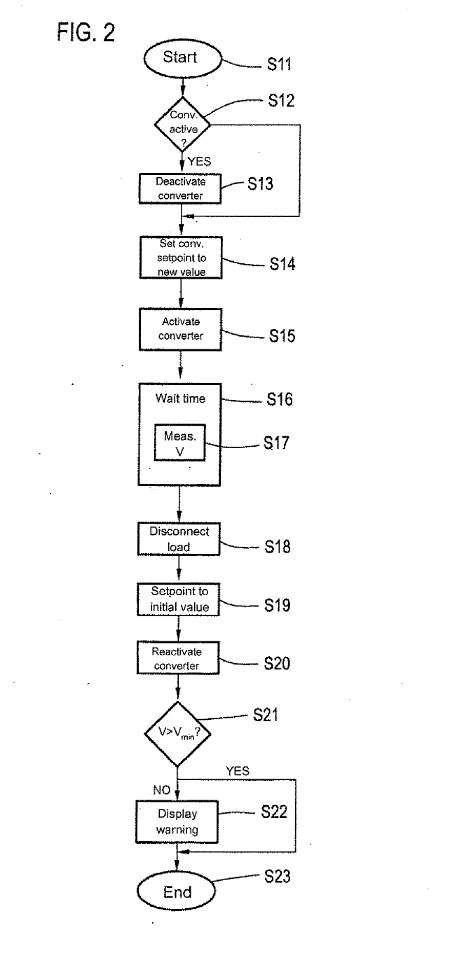

FIG. 2 a flow diagram of another exemplary embodiment of the method according to the invention,

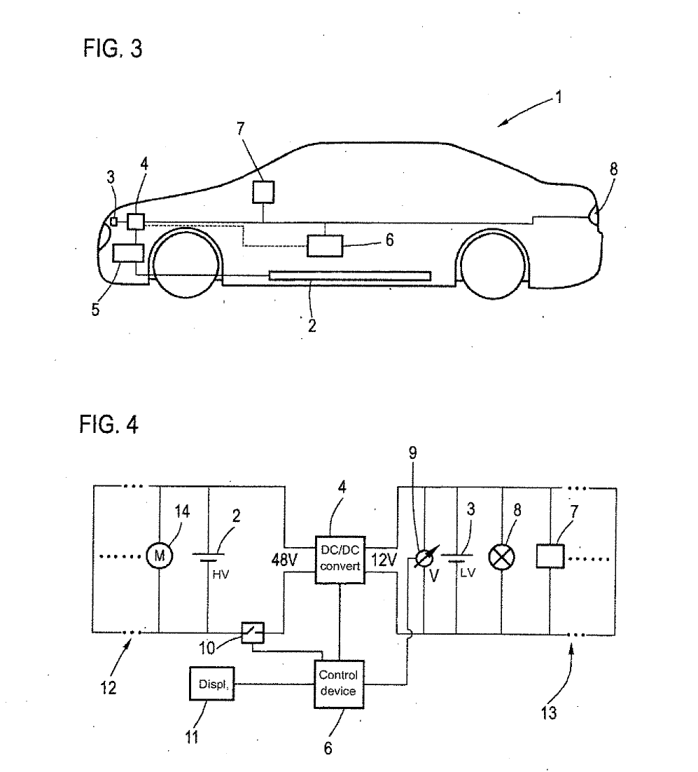

FIG. 3 an motor vehicle according to the invention, and

FIG. 4 a schematic diagram of the higher voltage electrical system and the low-voltage electrical system of the motor vehicle according to the invention.

For sake of clarity, it is assumed in the following exemplary embodiments that the first energy store is a low-voltage energy store and the second energy store is a higher voltage energy store, and that a warning signal is outputted to the driver as a signal. A skilled artisan will of course appreciate that energy stores with the same rated voltage can be used, or that the first energy store may also have a higher nominal voltage than the second energy store and that the signal can also trigger additional or alternative functions in the motor vehicle.

FIG. 1 shows a flow diagram of a method for testing a low-voltage energy store. The method is started in step S1, for example by switching on the ignition. In step S2, a load having a low impedance is connected to the low-voltage energy store. The connection is established, for example, by closing a switch with a control device. Due to the connection with a load having a low impedance, large currents are supplied by the low-voltage energy store. The importance of the internal resistance of the low-voltage energy store increases with increasing supplied amperage. This can cause the voltage to decrease, which can be determined in step S4 by measuring the voltage. A wait interval begins after step S2 in step S3. The length of the wait interval S3 can be determined for example by a digital timer. Alternatively, however, an analog circuit may be used that closes for example a switch only for a very short period of time. In the method according to the invention, the wait interval is chosen to be sufficiently long, so that a measurement takes place only at the time when the voltage drop at the low-voltage energy store has stabilized. Longer intervals for stabilization may be necessary for example when the internal impedance of the low-voltage energy store or the impedance of the load has large inductive or capacitive components.

For example, if a lead-acid storage battery which is installed in most vehicles with internal combustion engines is used as a low-voltage energy store and the impedance of the load is approximately selected so that currents flow that are similar to those when starting a vehicle with a combustion engine, then this consumption can be maintained for one or more seconds, without this consumption harming the low-voltage energy store. Typically, however, much shorter periods of a few ms or even below 1 ms are sufficient. After a sufficiently long wait interval, within the step S3, i.e. during the wait, at least one measured value is recorded in step S4 by the voltage measuring device.

The voltage measuring device may be designed to continuously measure the voltage drop across the low-voltage energy store. If the measurement frequency is sufficiently high to allow several measurements to be taken within the wait interval S3, then it is sufficient in step S4 to read out the last measured value or the last measured values from a measurement buffer. If this is not the case, the control device can also trigger the voltage measuring device to selectively make a voltage measurement. Measuring several voltages in step S4 may be advantageous for obtaining a total measured value with a smaller error by averaging several measurements. However, the measurement of several values in step S4 can also be used to ensure that the voltage drop across the low-voltage energy store voltage is stable, i.e. it no longer oscillates, which may be the case when a load is suddenly switched in. It may also be advantageous for diagnosing a low-voltage energy store to record a temporal profile of the voltage drop across the low-voltage power storage during the connection with the low impedance load. This is not usually necessary when performing a test exclusively of the low-voltage energy store.

After the measured value or all measured values are recorded in step S4 and after the wait interval S3 has ended, the low-voltage energy store can be disconnected from the load in step S5. The connection of the low-impedance load to the low-voltage energy store causes large current flows and thus a fast discharge of the low-voltage energy store as well as heating of the low-voltage energy store, the cables and other components involved. Therefore, the connection should be disconnected again in step S5 as soon as it is no longer necessary.

The following steps are only implemented to aid in the evaluation of the measurement result. These can potentially be carried out before the step S5; however, as described above, step S5 should advantageously be performed as early as possible. In step S6, the voltage measured in step S4 is compared with a minimum value of the voltage. As already described, the voltage is substantially dependent on the internal resistance of the low-voltage energy store. A high internal resistance of the low-voltage energy store may indicate that the state of charge of the low-voltage energy store is low, or that the low-voltage energy store has other defects that reduce the performance. If the measured voltage value is above a limiting voltage value, then it can be assumed that the low-voltage energy store is sufficiently powerful for the driving operation, and the process is terminated in step S8. However, if the measured voltage is below the predetermined limiting voltage value, a signal is issued to the driver in step S7 to inform the driver that the condition of the low-voltage energy store is inadequate to ensure that all the vehicle systems operate reliably during the vehicle operation.

It should be noted that multiple limiting values can also be used in step S6 that may cause different reactions depending on the defined limiting voltage value, below which the voltage drops. Thus, if the voltage in step S6 drops slightly below the defined limiting voltage value, only a warning symbol may be displayed in the view of the driver in step S7. If the voltage falls below of another limiting value, a haptic or acoustic signal may be outputted. Additionally, when the voltage in step S6 falls below limiting voltage values, individual not safety-relevant vehicle systems, in particular pure entertainment systems, may be disabled. If the method is performed when commencing travel, driving in the motor vehicle may be prevented, for example by shutting down the engine, or driving with a purely electric drive may be prevented when the voltage falls below a certain limiting voltage value.

FIG. 2 shows a flow diagram of a method for testing a low-voltage energy store, where a DC/DC converter is used as a load. After the start of the method in step S11, it is checked in step S12 whether the DC/DC converter is active. Depending on its design, the DC/DC converter may always be active when connected to both voltage systems, the low-voltage electrical system and the higher-voltage electrical system, of the motor vehicle. However, it is also possible that the DC/DC converter is only active, i.e. that current flows from one electrical system to the other electrical system, when the DC/DC converter is controlled by certain control signals. If the DC/DC converter is active, it is then deactivated in step S13 or disconnected from one or both electrical systems. Although the DC/DC converter is indeed to be used in the method as a load in order to achieve the shortest possible duration of the test, it may be advantageous to first disconnect the DC/DC converter from the electrical systems and to then reconnect the DC/DC converter to the electrical systems later, but only for the time interval during which it will serve as the load.

After having determined in step S12 that the DC/DC converter is not active or was deactivated in step S13, the target voltage or current setpoint of the controlled DC/DC converter is set to a new value in step S14. The DC/DC converter in hybrid vehicles is generally configured under normal driving conditions so that current is transported from the higher voltage electrical system to the low-voltage electrical system for operating the low-voltage components of the motor vehicle and for charging the low-voltage energy store. As mentioned earlier, hybrid vehicles frequently use bidirectional DC/DC converters, which also allow current to be transported from low-voltage electrical system to the higher-voltage electrical system, for example for the purpose of aiding in starting the car. The direction of the transported current in controlled converters can be defined by adjusting the target voltage or current values. It should be noted that the target values define the output voltage of the DC/DC control device even for current-controlled DC/DC control devices. Regardless of whether the DC/DC control device is voltage or current controlled, the target output voltage can be controlled via a setpoint variable. If the nominal output voltage is smaller than the external voltage applied to the DC/DC converter, i.e. generally smaller than the voltage drop at the higher-voltage energy store, then current flows from the higher voltage circuit to the low-voltage circuit, thereby charging the low-voltage energy store, This is the range in which the DC/DC converter is often operated in the operation of the motor vehicle. However, if the setpoint is increased to a point where the voltage on the higher voltage side of the DC/DC converter is higher than the voltage drop at the higher voltage energy store, then the higher voltage energy store is charged, with the necessary energy being withdrawn from the low-voltage electrical system, i.e. the low-voltage energy store.

For testing purposes, large amounts of current should be drawn from the low-voltage energy store. Therefore, the target value of the DC/DC converter is set in step S14 so that the output voltage of the DC/DC converter in well above the voltage drop at the higher voltage energy store. In step S15, the DC/DC converter is subsequently activated or connected to the both voltage electrical systems. The DC/DC converter thus transports, as described above, energy from the low-voltage energy store to the higher-voltage energy store, meaning that the DC/DC converter operates in the low-voltage circuit as a load. Depending on the setting of setpoint in step S14, a current of several 10 A to several 100 A can be drawn from the low-voltage energy store after establishing the connection in step S15. The steps S16, S17 and S18 corresponding to steps S3, S4 and S5 of FIG. 1. In step S16, a certain wait interval is observed after establishing the connection, during which in step S17 one or several voltage values are recorded by the voltage measuring device. In step S18, the DC/DC converter is deactivated or disconnected from at least one of the electrical systems. Since the DC/DC converter should be available outside the test interval for its normal tasks, the setpoint is reset to an initial value in step S19, which usually corresponds to slow charging of the low-voltage energy store from the higher voltage energy store and from the remaining higher voltage electrical system. The DC/DC converter is then reactivated in step S20 or reconnected to the electrical systems. Comparing the voltage with a minimum value in step S21 and signaling in step S22 and terminating the process in step S23 in turn correspond to the respective steps S6, S7 and S8 of FIG. 1

FIG. 3 shows an motor vehicle 1 according to the invention. The motor vehicle 1 includes a higher voltage battery 2 and a low-voltage battery 3. The higher voltage battery 2 supplies to a voltage of 48 V, the low-voltage battery 3 a voltage of 12 V. The motor vehicle 1 thus has two onboard electrical systems, an electrical system operating at 48V and an electrical system operating at 12 V. The two onboard electrical systems are connected via the DC/DC converter 4.

The vehicle 1 has a hybrid motor 5, which consists of an internal combustion engine and two electric motor/generators and a planetary gear connecting these three components. Hybrid engines are known in the art and the function of the hybrid motor 5 will therefore not be discussed here in detail. It is essential that for starting the internal combustion engine of the hybrid motor 5 at least one of the electric motors is operated by drawing current from the higher voltage battery 2. An electric motor, which is supplied from a higher voltage battery 2, serves here also as a starter. The low-voltage battery 3 is therefore not tested when the engine is started. The low-voltage battery 3 powers in the motor vehicle 1, for example, the headlights 8 as well as various low-voltage systems 7 in the interior of the vehicle and a control device 6. The control device 6 can control the DC/DC converter. In normal vehicle operation and depending for example on the state of charge of the low-voltage battery 3, the low-voltage battery can therefore be charged more strongly or not at all simply by varying with the control device 6 the setpoints of the DC/DC converter 4.

The low-voltage battery can be tested by briefly disconnecting the DC/DC converter 4 from one of the onboard electrical systems, by subsequently adapting with the control device 6 the setpoint of the control of the DC/DC converter 4 and by then briefly connecting the DC/DC converter to the onboard electrical systems, while measuring the voltage drop across the low-voltage battery 3.

FIG. 4 shows a schematic diagram of the two onboard electrical systems of the motor vehicle shown in FIG. 3. The higher-voltage electrical system shown at the left of the DC/DC converter 4 includes a higher voltage battery 2 and at least one electric motor 14. The electric motor 14 may also be operated as a generator. It is indicated in the area 12 that other components may be present in the higher voltage electrical system. One polarity of the higher voltage electrical system is fixedly connected to the DC/DC converter 4, whereas the other polarity is coupled to the DC/DC converter 4 via a switch 10. When the control device 6 opens the switch 10, current is prevented from flowing from the low-voltage electrical system to the higher voltage electrical system, or vice versa, over longer periods of time.

The low-voltage system shown at the right includes the low-voltage battery 3, the headlights 8, several low-voltage loads 7 in the vehicle interior, and other components 13. The voltage drop across the low-voltage battery 3 is measured by the voltage measuring device 9. The voltage measuring device 9 can be read out by the control device 6. The control device 6 can also specify a setpoint for the DC/DC converter 4. In addition, the control device can output a signal to the driver of the motor vehicle via a display device 11 which is located in the field of view of the driver. For carrying out the method for testing the low-voltage battery, the switch 10 is initially opened by the control device 6 to prevent current conduction through the DC/DC converter 4. The setpoint of the DC/DC converter 4 is subsequently adjusted by the control device 6. Because the DC/DC converter is operated during the test only for a very short time interval, for example, the maximum output voltage can be outputted. The control device 6 then closes the switch 10. Large currents then flow from the low-voltage battery 3 through the DC/DC converter 4 and charge the higher voltage battery 2. After a short wait interval, the voltage value of the voltage measuring device 9 is read by the control device 6. Subsequently, the switch 10 is opened again. If the read-out voltage value of the voltage measuring device 9 is greater than a predetermined voltage value, the process is terminated. However, if the value is smaller, the display device 11 is controlled by the control device 6 so that a warning is outputted to a driver.

1.-17. (canceled)

18. A method for testing in a motor vehicle a first energy store which operates a plurality of vehicle systems, wherein the motor vehicle comprises a second energy store which provides at least electrical energy required for starting the motor vehicle, and a control device, the method comprising:
connecting by way of the control device the first energy store to a load having an impedance that is lower than a minimum total impedance of a parallel circuit of a specified selection of the plurality of vehicle systems for a fixed time interval, wherein the load is a bidirectional DC/DC converter of the motor vehicle,
measuring with a voltage measuring device a voltage dropping at the first energy store at least once within the fixed time interval, and
outputting with the control device a signal when the voltage drops below a predetermined limiting value.

19. The method of claim 18, wherein the first energy store is a low-voltage energy store and the second energy store is a higher voltage energy store.

20. The method of claim 18, wherein the method is performed before the motor vehicle is being driven.

21. The method of claim 18, wherein the method is performed in at least one situation selected from turning on an ignition of the motor vehicle, opening a vehicle door and detecting with a detection device a wireless key belonging to the vehicle at a predetermined maximum distance.

22. The method of claim 18, wherein the method is performed at regular intervals occurring during operation of the motor vehicle or when the motor vehicle is at a standstill.

23. The method of claim 18, wherein when connecting the first energy store to the load, a reference voltage or a reference current of the DC/DC converter is adjusted first, whereafter the DC/DC converter is operated for the duration of the fixed time interval with the adjusted reference voltage or the adjusted reference current.

24. The method of claim 18, wherein the load charges the second energy store during the fixed time interval.

25. The method of claim 18, wherein the fixed time interval is between 2 ms and 60 s.

26. The method of claim 18, wherein the fixed time interval is between 200 ms and 40 s.

27. The method of claim 18, wherein the fixed time interval is between 1 s and 30 s.

28. The method of claim 18, wherein when the first energy store is operative and no signal is outputted, the impedance of the load is selected so that a current supplied by the first energy store during the fixed time interval has a maximum value of at least 40 A.

29. The method of claim 28, wherein the maximum value is at least 200 A.

30. The method of claim 28, wherein the maximum value is at least 300 A.

31. The method of claim 18, wherein, when the control device outputs the signal, a warning signal selected from an acoustic, an optical or a haptic signal is outputted to a driver by a notification device of the motor vehicle.

32. The method of claim 18, wherein, when the control device outputs the signal, the motor vehicle is shut off.

33. The method of claim 32, wherein the motor vehicle is shut off when the motor vehicle is at a standstill.

34. The method of claim 18, wherein when the control device outputs the signal, use of at least one vehicle system is inhibited.

35. The method of claim 34, wherein the at least one inhibited vehicle system comprises at least one system selected from a communication system, an entertainment system, a driver assistance system, a sensor system, a heating system, an air conditioning system, and a navigation system.

36. The method of claim 18, wherein when the control device outputs the signal, the first energy store is disconnected from an onboard electrical system of the motor vehicle.

37. The method of claim 18, wherein after the control device has outputted the signal, the motor vehicle is prevented from changing into an operating mode with an exclusively electrical driving operation, or the motor vehicle exits an operating mode with an exclusively electrical driving operation, or both.

38. A motor vehicle comprising:
a first energy store for operating a plurality of vehicle systems,
a second energy store which provides at least electrical energy required for starting the motor vehicle,
a voltage measuring device configured to measure a voltage dropping at the first energy store at least once within a fixed time interval, and at least one control device configured to connect the first energy store to a load having an impedance that is lower than a minimum total impedance of a parallel circuit of a specified selection of the plurality of vehicle systems for the fixed time interval, wherein the load is a bidirectional DC/DC converter of the motor vehicle, and to output a signal when the voltage drops below a predetermined limiting value.

39. The motor vehicle of claim 38, wherein the control device is configured to determine the lower limiting value of the voltage dropping at the first energy store, to read out the voltage measured by the voltage measuring device, and to output the signal, when a measured voltage is lower than the lower limiting value.

40. The motor vehicle of claim 39, wherein the at least one control device or an additional control device is configured to connect the first energy store to the load and to evaluate the signal.

41. The motor vehicle of claim 40, wherein the at least one control device or the additional control device or a third control device is configured to define a nominal current or a nominal voltage of the DC/DC converter.
